(19) United States
(12) Patent Application Publication
(10) Pub. No.: US 2009/0097206 A1
(43) Pub. Date: Apr. 16, 2009

(54) LOOP HEAT PIPE AND ELECTRONIC EQUIPMENT

(75) Inventor: Kentaro TOMIOKA, Sayama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/211,421

(22) Filed: Sep. 16, 2008

(30) Foreign Application Priority Data
Oct. 15, 2007 (JP) 2007-268096

(51) Int. Cl. H05K 7/20; F28D 15/00

(52) U.S. Cl. 361/701; 165/104.26

(57) ABSTRACT

A loop heat pipe includes a vessel having a flow path formed in a looped shape and a working fluid sealed in the vessel, and the vessel includes a first wick provided at least in a opposing area in an evaporation part and a second wick adjacent to the first wick 61 from the side of a liquid return pipe. The vessel has a first wall facing a heat generating component and a second wall opposed to the first wall. The first wick has a first portion provided in the first wall and a second portion provided in the second wall with space from the first portion. The second wick is provided to cover the entire cross-section of the flow path between the first wall and the second wall.

### CROSS-REFERENCE TO RELATED APPLICATIONS

This application is based upon and claims the benefit of priority from Japanese Patent Application No. 2007-268096, filed on Oct. 15, 2007, the entire content of which are incorporated herein by reference.

### BACKGROUND

1. Field

One embodiment of the invention relates to a loop heat pipe for cooling a heat generating component and an electronic equipment provided with the loop heat pipe.

2. Description of the Related Art

A document JP-A-2007-163076 discloses a circulation-type heat transporting device (loop heat pipe) applied to an electronic equipment. The heat transporting device includes a looped flow path through which a working fluid flows in one direction by a capillary force. The looped flow path is configured by an evaporation part, a steam pipe, a condensation part, and a liquid pipe.

The evaporation part has a porous body placed in a base part to be in contact with a heat generating component. A liquid working fluid is supplied from the liquid pipe to the evaporation part by a capillary force in the porous body. When the heat generating component generates heat, the heat causes the working fluid to evaporate. Accordingly, the heat generating component is deprived of the heat by the working fluid as latent heat of vaporization. The working fluid which becomes steam moves through the steam pipe to the condensation part and is cooled in the condensation part and is liquefied. The liquefied working fluid is again returned to the evaporation part through the liquid pipe.

In the heat transporting device, the working fluid is circulated by the capillary force in the porous body. In this case, unless the capillary force is sufficiently large as compared with the pressure loss in the flow path, the working fluid does not well flow and it is feared that the operation of the loop heat pipe may become unstable.

### SUMMARY

According to a first aspect of the present invention, there is provided a loop heat pipe including: a vessel that forms a flow path in a looped shape; and a working fluid that is sealed in the vessel, wherein the vessel includes: an evaporation part that is to be thermally connected to a heat generating component for vaporizing the working fluid, the evaporation part including opposing area to be opposed to the heat generating component; a condensation part that liquefies the vaporized working fluid; a steam pipe that connects the evaporation part and the condensation part to allow the working fluid vaporized at the evaporation part to flow toward the condensation part; a liquid return pipe that connects the condensation part and the evaporation part to allow the working fluid condensed at the condensation part to flow toward the evaporation part; a first wick that is provided in the flow path at the opposing area of the evaporation part; and a second wick that is provided in the flow path to be adjacent to the first wick at a side where the liquid return pipe is provided, wherein the evaporation part has a first wall that faces the heat generating component and a second wall that is opposed to the first wall, wherein the first wick has a first portion provided on the first wall and a second portion provided on the second wall to be separated away from the first portion, wherein the second wick is provided to cover the entire cross-section of the flow path between the first wall and the second wall, and wherein the evaporation part is provided with a heat connection member that extends from the first wall through the flow path to the second wall for thermally connecting the first wall and the second wall.

According to a second aspect of the present invention, there is provided a loop heat pipe including: a vessel that forms a flow path in a looped shape; and a working fluid that is sealed in the vessel, wherein the vessel includes: an evaporation part that is to be thermally connected to a heat generating component for vaporizing the working fluid, the evaporation part including opposing area to be opposed to the heat generating component; a condensation part that liquefies the vaporized working fluid; a steam pipe that connects the evaporation part and the condensation part to allow the working fluid vaporized at the evaporation part to flow toward the condensation part; a liquid return pipe that connects the condensation part and the evaporation part to allow the working fluid condensed at the condensation part to flow toward the evaporation part; a first wick that is provided in the flow path at the opposing area of the evaporation part; and a second wick that is provided in the flow path to be adjacent to the first wick at a side where the liquid return pipe is provided, wherein the evaporation part has a first wall that faces the heat generating component and a second wall that is opposed to the first wall, wherein the first wick has a first portion provided on the first wall and a second portion provided on the second wall to be separated away from the first portion, and wherein the second wick is provided to cover the entire cross-section of the flow path between the first wall and the second wall.

According to a third aspect of the present invention, there is provided an electronic equipment including: a cabinet; a heat generating component installed in the cabinet; and a loop heat pipe including: a vessel that forms a flow path in a looped shape; and a working fluid that is sealed in the vessel, wherein the vessel includes: an evaporation part that is to be thermally connected to a heat generating component for vaporizing the working fluid, the evaporation part including opposing area to be opposed to the heat generating component; a condensation part that liquefies the vaporized working fluid; a steam pipe that connects the evaporation part and the condensation part to allow the working fluid vaporized at the evaporation part to flow toward the condensation part; a liquid return pipe that connects the condensation part and the evaporation part to allow the working fluid condensed at the condensation part to flow toward the evaporation part; a first wick that is provided in the flow path at the opposing area of the evaporation part; and a second wick that is provided in the flow path to be adjacent to the first wick at a side where the liquid return pipe is provided, wherein the evaporation part has a first wall that faces the heat generating component and a second wall that is opposed to the first wall, wherein the first wick has a first portion provided on the first wall and a second portion provided on the second wall to be separated away from the first portion, and wherein the second wick is provided to cover the entire cross-section of the flow path between the first wall and the second wall.

### BRIEF DESCRIPTION OF THE SEVERAL VIEWS OF THE DRAWINGS

A general configuration that implements the various feature of the invention will now be described with reference to the drawings. The drawings and the associated descriptions are provided to illustrate embodiments of the present invention and not to limit the scope of the present invention.

FIG. 1 is a perspective view of a portable computer according to a first embodiment of the present invention.

FIG. 2 is a sectional view of a loop heat pipe according to the first embodiment.

FIG. 3 is a sectional view of an evaporation part shown in FIG. 2.

FIG. 4 is a sectional view of the evaporation part taken on line IV-IV shown in FIG. 3.

FIG. 5 is a sectional view of the evaporation part taken on line V-V shown in FIG. 3.

FIG. 6 is a sectional view of the evaporation part taken on line VI-VI shown in FIG. 3.

FIG. 7 is a sectional view of the evaporation part taken on line VII-VII shown in FIG. 3.

FIG. 8 is a sectional view to show one modified example of the evaporation part shown in FIG. 3.

FIG. 9 is a sectional view to show another modified example of the evaporation part shown in FIG. 3.

FIG. 10 is a sectional view of a loop heat pipe according to a second embodiment of the present invention.

FIG. 11 is a sectional view of a loop heat pipe according to a third embodiment of the present invention.

FIG. 12 is a sectional view of an evaporation part according to a fourth embodiment of the present invention.

FIG. 13 is a sectional view of the evaporation part taken on line XIII-XIII shown in FIG. 12.

FIG. 14 is a sectional view of the evaporation part taken on line XIV-XIV shown in FIG. 12.

FIG. 15 is a sectional view of an evaporation part according to a fifth embodiment of the present invention.

FIG. 16 is a sectional view to show one modified example of the evaporation part shown in FIG. 15.

FIG. 17 is a sectional view of an evaporation part according to a sixth embodiment of the present invention.

FIG. 18 is a sectional view to show one modified is example of the evaporation part shown in FIG. 17.

### DETAILED DESCRIPTION

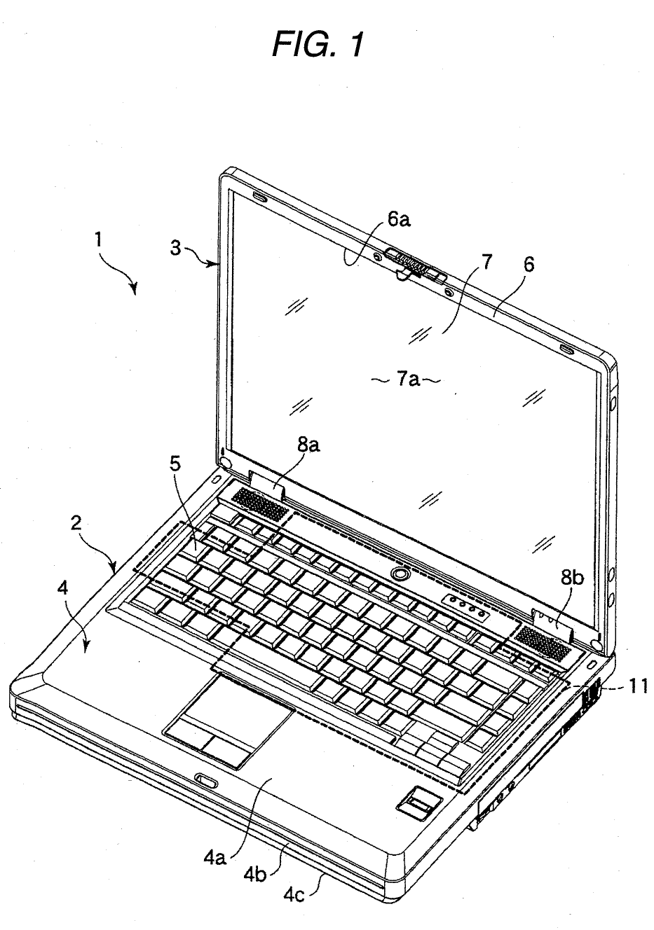

A portable computer according to embodiments of the present invention will be described with reference to the accompanying drawings. FIGS. 1 to 7 show a portable computer 1 described as an example of an electronic equipment according to a first embodiment.

As shown in FIG. 1, the portable computer 1 is provided with a main unit 2 and a display unit 3. The main unit 2 has a cabinet 4 formed in a box shape. The cabinet 4 has a top wall 4a, a peripheral wall 4b, and a bottom wall 4c. The top wall 4a supports a keyboard 5. An exhaust hole (not shown) is formed on the peripheral wall 4b.

The display unit 3 includes a display housing 6 and a display device 7 housed in the display housing 6. The display device 7 has a display screen 7a exposed to the outside of the display housing 6 through an opening 6a formed in the front of the display housing 6.

The display unit 3 is supported at the rear end of the cabinet 4 through a pair of hinge parts 8a and 8b. Thus, the display unit 3 is configured to be pivotable between a closed position at which the display unit is tilted so as to cover the top wall 4a from above and an open position at which the display unit stands up so as to expose the top wall 4a.

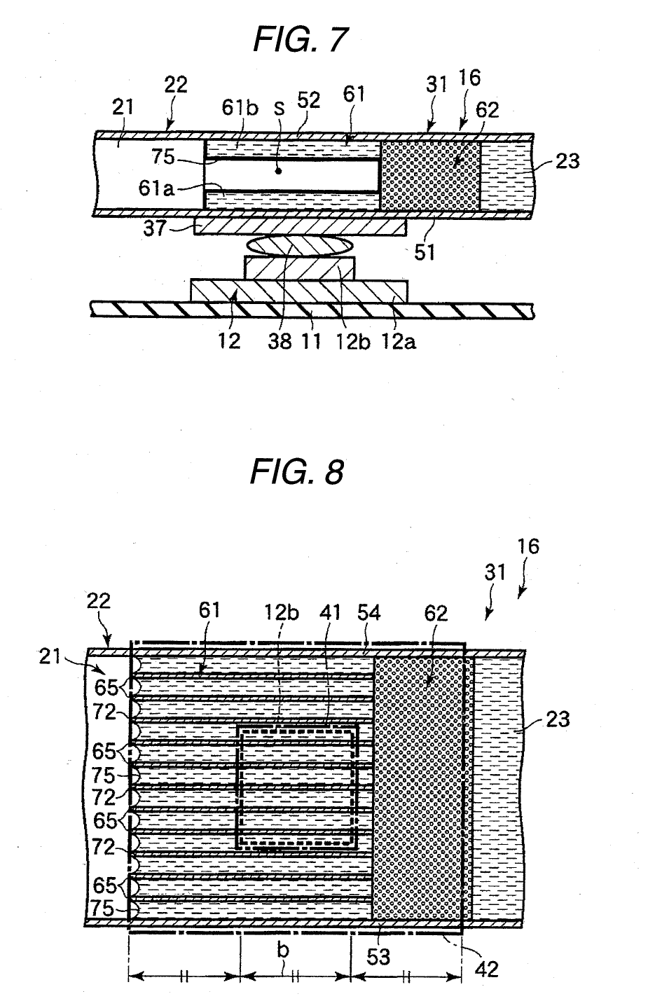

As shown in FIG. 1, a circuit board 11 is housed in the cabinet 4. A heat generating component 12 is mounted on the circuit board 11 (see FIG. 7). The heat generating component 12 is an electronic component that generates heat when in operation, for example; a CPU, a graphic chip, a north bridge (registered trademark), memory, etc., is named as a specific example of the heat generating component 12. However, the heat generating component 12 is not limited to the above-mentioned components and various components whose heat diffusion is desired correspond to the heat generating component 12.

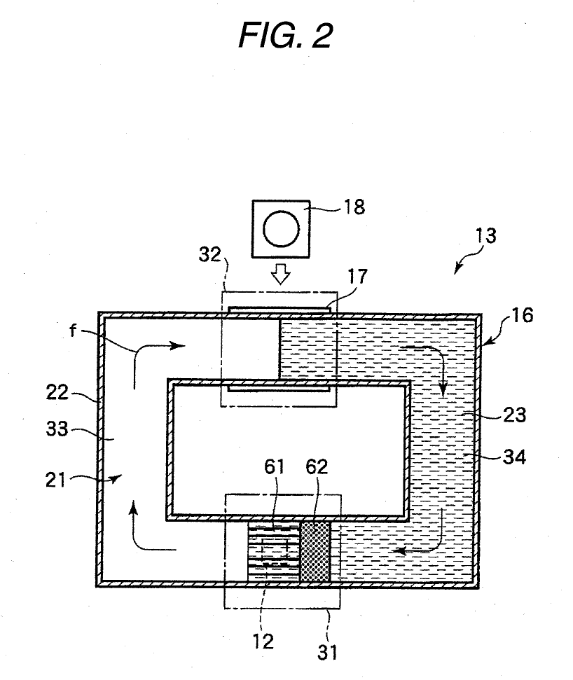

FIG. 2 schematically shows a configuration example of a cooling unit 13 installed in the portable computer 1. The cooling unit 13 includes a loop heat pipe 16, a radiation member 17, and a cooling fan 18. A radiation fin unit having a plurality of fins is named as an example of the radiation member 17. The cooling fan 18 ejects air toward the radiation member 17, for example, for cooling the radiation member 17.

The loop heat pipe 16 transports heat of the heat generating component 12 to the radiation member 17. The loop heat pipe 16 has a vessel 22 having a flow path 21 formed in a looped shape and a working fluid 23 sealed in the vessel 22. The loop heat pipe 16 is a heat transporting device of natural circulation type wherein the working fluid 23 flows in one direction in the flow path 21 by a capillary force.

More particularly, the loop heat pipe 16 includes an evaporation part 31, a condensation part 32, a steam pipe 33, and a liquid return pipe 34. The evaporation part 31 is a light reception part. The evaporation part 31 is connected thermally to the heat generating component 12 and receives heat from the heat generating component 12. The heat causes the working fluid 23 to be heated and vaporized in the evaporation part 31. The condensation part 32 is a radiation part. The condensation part 32 is connected thermally to the radiation member 17 for cooling and liquefying the vaporized working fluid

The steam pipe 33 is provided between the evaporation part 31 and the condensation part 32, and the working fluid 23 vaporized in the condensation part 32 flows toward the evaporation part 31 through the steam pipe 33.

Next, an example of the loop heat pipe 16 will be described. The vessel 22 is formed of a copper material, for example. The vessel 22 is formed flat as shown in FIG. 5. Width B of the vessel 22 is 40 mm, for example, and thickness T of the vessel 22 is 0.8 mm, for example. The vessel 22 is formed by putting two plate members on each other with a space as the flow path 21 between, for example. Water, alcohol, ammonia, butane, an antifreezing solution, etc., is named as a specific example of the working fluid 23.

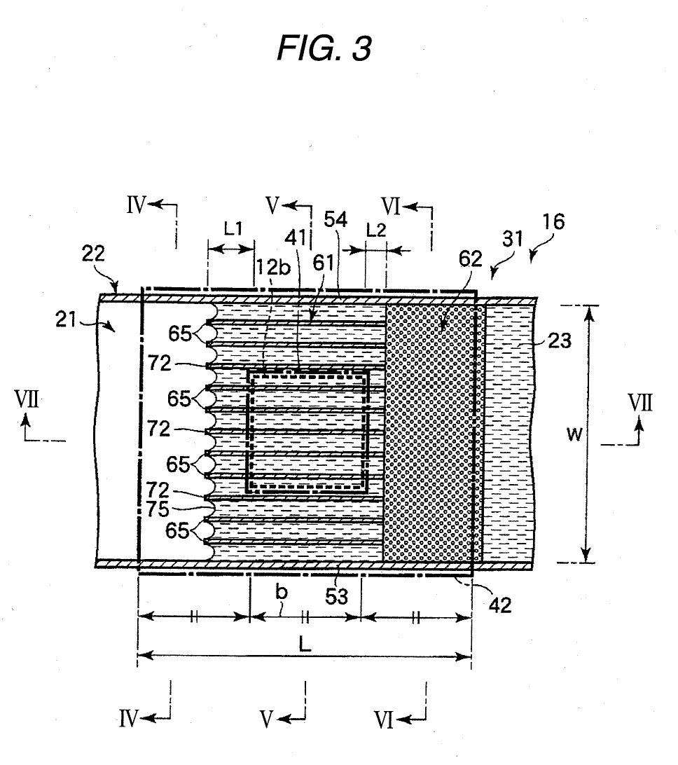

Next, the evaporation part 31 will be described in detail with reference to FIGS. 3 to 7. FIGS. 3 to 7 schematically show the shape of the evaporation part 31. As shown in FIGS. 5 and 7, the evaporation part 31 has a shape wherein a thermal contact portion is formed flat. The evaporation part 31 is opposed to the heat generating component 12 and is also thermally connected to the heat generating component 12 through a thermal diffusion plate 37, for example. At this time, for example, a thermal connection material 38 is intervened between the heat generating component 12 and the thermal diffusion plate 37. The thermal connection material 38 is, for example, heat exchanger grease or a heat exchanger sheet and more solidifies the thermal connection between the heat generating component 12 and the thermal diffusion plate 37. The thermal diffusion plate 37 is not an indispensable member and the loop heat pipe 16 may be in direct contact with the heat generating component 12.

Next, several areas formed in the evaporation part 31 will be described with reference to FIG. 3. The evaporation part 31 contains an opposing area 41 and an effective evaporation area 42. As shown in FIG. 3, the opposing area 41 is an area opposed to the heat generating component 12. The expression “opposed to the heat generating component” mentioned in the invention contains not only the case where the evaporation part (area) is opposed directly to the heat generating component, but also the case where the evaporation part (area) is opposed to the heat generating component with a thermal diffusion plate, etc., intervened between the evaporation part (area) and the heat generating component, for example.

The opposing area 41 has the same size as the outer shape of the heat generating component 12, for example. For example, if the heat generating component 12 has a substrate 12a and a chip 12b mounted on the substrate 12a, the opposing area 41 has the same size as the outer shape of the chip 12b, for example.

As shown in FIG. 3, the effective evaporation area 42 contains a portion for coming in direct thermal contact with the heat generating component 12 or coming in thermal contact with the heat generating component 12 through a thermal diffusion plate, etc., and a neighborhood area. Specifically, the effective evaporation area 42 contains an area extending the length corresponding to width b of the heat generating component 12 before and after (namely, in an upward direction and a downward direction of the working fluid 23) from both ends of the opposing area 41 along the flow direction of the working fluid 23 in addition to the opposing area 41.

As a specific example, when the width b of the heat generating component 12 along the flow direction of the working fluid 23 is 10 mm, length L of the effective evaporation area 42 is 30 mm. The effective evaporation area 42 is provided on the full width of the flow path 21 along the direction orthogonal to the flow of the working fluid 23 (namely, width W direction).

As shown in FIG. 5, the vessel 22 has first and second walls 51 and 52 and a pair of side walls 53 and 54. The first wall 51 faces the heat generating component 12 and is in contact with the thermal diffusion plate 37. It has a pair of both side margins 51a and 51b extending along the flow direction of the working fluid 23. The second wall 52 faces an opposite side to the heat generating component 12. It is opposed to the first wall 51 with a space as the flow path 21 between. The second wall 52 has a pair of both side margins 52a and 52b extending along the flow direction of the working fluid 23.

The pair of side walls 53 and 54 is provided separately in both side margins 51a and 51b of the first wall 51 and joins both side margins 51a and 51b of the first wall 51 to both side margins 52a and 52b of the second wall 52. As described above, the vessel 22 is formed flat and, for example, the area of the second wall 52 is larger than the total area of the pair of side walls 53 and 54. That is, letting the width W of the flow path 21 be length A and height H of the flow path 21 be length B, the relation of A>2B holds.

As shown in FIG. 3, first and second wicks 61 and 62 are provided in the evaporation part 31. The first wick 61 is provided in the effective evaporation area 42. The first wick 61 is provided at least in the opposing area 41 and is also provided in an area out of the opposing area 41. As shown in FIG. 3, distance L1 between an end of the first wick 61 oriented downward of the working fluid 23 and an end of the heat generating component 12 oriented downward is smaller than the width d of the heat generating component 12, for example. Distance L2 between an end of the first wick 61 oriented upward of the working fluid 23 and an end of the heat generating component 12 oriented upward is smaller than the width d of the heat generating component 12, for example. The first wick 61 is provided over the full width of the flow path 21 along the direction orthogonal to the flow of the working fluid 23, for example.

As shown in FIG. 5, the first wick 61 has first and second portions 61a and 61b provided away from each other. The first portion 61a is provided in the first wall 51. The second portion 61b is provided in the second wall 52 with space S between the first portion 61a and the second portion 61b.

Each of the first and second portions 61a and 61b is formed of a plurality of plate members 65 along the flow direction of the working fluid 23. The plate member 65 is called partition plate, for example. The plate member 65 has a height smaller than a half of the height H of the flow path 21, for example. In the first portion 61a, the plate members 65 stand up in the flow path 21 from the first wall 51 and form a groove along the flow direction of the working fluid 23. In the second portion 61b, the plate members 65 stand up in the flow path 21 from the second wall 52 and form a groove along the flow direction of the working fluid 23.

The plate members 65 of each of the first and second portions 61a and 61b are provided in 0.1-mm pitches, for example, in the direction orthogonal to the flow of the working fluid 23. The plate members 65 of each of the first and second portions 61a and 61b are formed integrally with the vessel 22, for example. Instead, the first wick 61 formed as a separate piece from the vessel 22 may be fitted into the vessel 22.

As shown in FIG. 3, the second wick 62 is adjacent to the first wick 61 from the side of the liquid return pipe 34. That is, the second wick 62 is provided upward from the first wick 61 in the flow direction of the working fluid 23. As shown in FIG. 6, the second wick 62 is provided to cover the entire cross-section of the flow path between the first wall 51 and the second wall 52. The second wick 62 is in contact with both of the first and second portions 61a and 61b of the first wick 61.

The second wick 62 stores the liquid working fluid 23 and also supplies the working fluid 23 in the amount corresponding to the evaporation amount in the first wick 61. The second wick 62 is formed of a porous body, for example. Specifically, it is sintered metal provided by burning and sintering mix powder of copper and synthetic resin, synthetic resin having heat resistance, or the like.

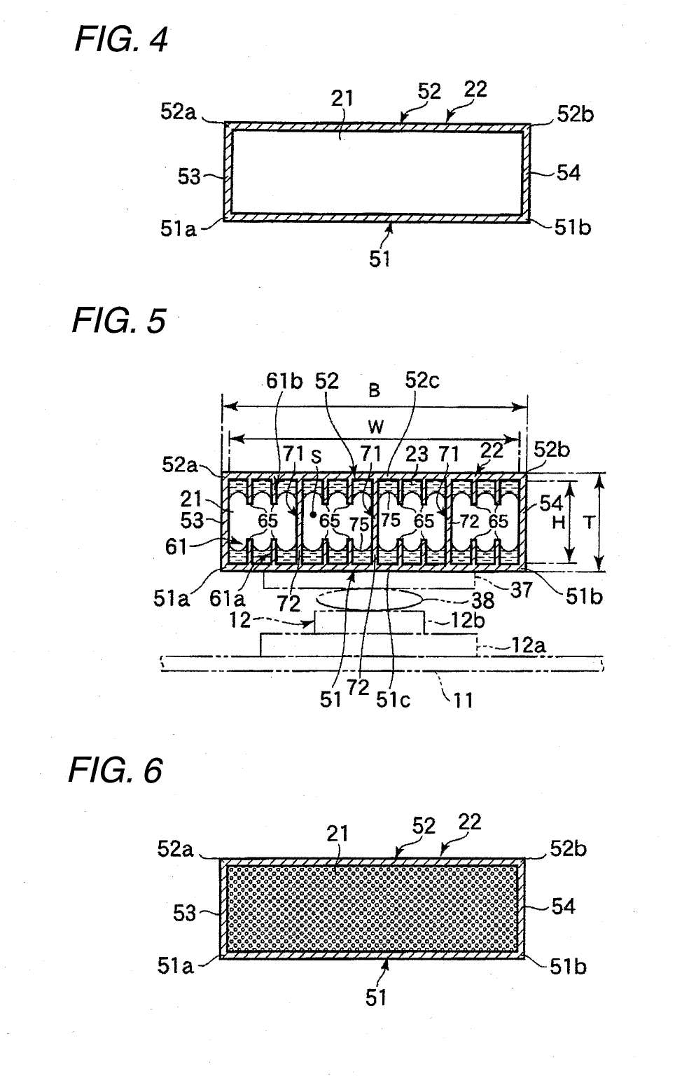

On the other hand, the side of the steam pipe 33 from the first wick 61 (namely, downward) is provided with no wick and is open, as shown in FIGS. 3 and 4.

A shown in FIG. 5, the evaporation part 31 is provided with a plurality of heat connection members 71, for example. The heat connection members 71 extend from the first wall 51 through the flow path 21 to the second wall 52 and thermally connect the first wall 51 to the second wall 52. The heat connection members 71 are provided between a center 51c of the first wall 51 and a center 52c of the second wall 52. The center 51c refers to an area of the first wall 51 out of both side margins 51a and 51b. The center 52c refers to an area of the second wall 52 out of both side margins 52a and 52b. Some of the heat connection members 71 are provided in the opposing area 41. That is, they thermally connect the first wall 51 in the opposing area 41 to the second wall 52.

The heat connection members 71 according to the embodiment are formed of plate members 72 along the flow direction of the working fluid 23 and extending between the first wall 51 and the second wall 52. In other words, some of the plate members formed in the first wall 51 arrive at the second wall 52, whereby the heat connect ion members 71 are formed. The plate members 72 are formed of a material having good thermal conductivity, for example, a metal material.

Next, the function and the operation of the loop heat pipe 16 will be described.

When the loop heat pipe 16 is in use, the heat generating component 12 generates heat. Most of the heat is first communicated to the first wall 51 of the evaporation part 31 through the thermal diffusion plate 37, for example. A part of the heat communicated to the first wall 51 is communicated to the first portion 61a of the first wick 61. Another part of the heat communicated to the first wall 51 is communicated to the second portion 61b of the first wick 61 through the heat connection members 71 and the second wall 52.

The liquid working fluid 23 is supplied to the first and second portions 61a and 61b. The working fluid 23 is heated and vaporized by the heat received by the first wick 61. At this time, the working fluid 23 absorbs the heat as latent heat.

The liquid return pipe 34 from the evaporation part 31 involves a high pressure loss as compared with the steam pipe 33 in the presence of the second wick 62. Thus, the vaporized working fluid 23 does not flow into the liquid return pipe 34 and flows into the condensation part 32 through the steam pipe 33. The condensation part 32 is cooled by the radiation member 17 and the cooling fan 18. The working fluid 23 arriving at the condensation part 32 is cooled in the condensation part 32 and releases heat and is liquefied.

When the working fluid 23 contained in the first wick 61 decreases because of evaporation of the working fluid 23, the liquid working fluid 23 corresponding to the evaporation amount of the working fluid 23 is supplied from the liquid return pipe 34 to the evaporation part 31 by the capillary force in the first and second wicks 61 and 62. More particularly, a capillary force occurs on an interface 75 between the first and second wicks 61 and 62. This capillary force causes the liquid working fluid 23 to be pulled from the liquid return pipe 34 to the evaporation part 31 for supplying the working fluid 23 from the second wick 62 to the first wick 61. Accordingly, the working fluid 23 liquefied in the condensation part 32 is returned to the evaporation part 31. Thus, the working fluid 23 is naturally circulated between the evaporation part 31 and the condensation part 32 in the direction of an arrow f in FIG. 2 and transports the heat of the heat generating component 12 to the radiation member 17.

According to the configuration described above, the capillary force occurring in the evaporation part 31 is large and thus the operation of the loop heat pipe 16 is more stabilized. That is, the loop heat pipe 16 allows the working fluid 23 to circulate by the capillary force in the wick. Thus, the magnitude of the capillary force has a large effect on stability of the operation of the loop heat pipe 16.

The thick line shown in FIG. 7 indicates a portion where an interface 75 occurs in the evaporation part 31. The term “interface” mentioned in the Specification refers to a boundary surface between the working fluid in a vapor phase and that in a liquid phase and a surface where the working fluid evaporates. If the first wick 61 is formed of the first and second portions 61a and 61b with space S between, the first wick 61 can form the interface 75 not only in the face opposed to the space S, but also in the face facing in the downward direction of the working fluid 23. That is, the large interface 75 can be formed in the first wick 61. Thus, the capillary force acting on the working fluid 23 increases and the operation of the loop heat pipe 16 is stabilized.

The effective evaporation area 42 is an area for best receiving the heat from the heat generating component 12 in the evaporation part 31. If the first wick 61 is provided in the effective evaporation area 42, the working fluid 23 is more easily vaporized.

By providing the second wick entire area between the first wall 51 and the second wall 52, the vaporized working fluid 23 can be circulated without flowing back in the flow path 21 even if the first wick 61 is formed of portions provided away from each other.

By providing the heat connection members 71 for thermally connecting the first wall 51 to the second wall 52, heat can also be efficiently communicated to the second portion 61b of the first wick 61 at a distance from the first wall 51. Accordingly, vaporization of the working fluid 23 from the second portion 61b can be promoted and the heat transport capability of the loop heat pipe 16 improves.

By forming each of the first and second portions 61a and 61b with the plate members 65, the first wick 61 can be molded at the same time as the vessel 22 is molded by extruding, etc., for example. Thus, the manufacturability of the loop heat pipe 16 is enhanced. By forming the second wick 62 of a porous body, it is easy to form the second wick 62 provided to cover the entire cross-section of the flow path between the first wall 51 and the second wall 52.

By forming the heat connection members 71 to extend from the first wall 51 through the flow path 21 to the second wall 52, the center 51c of the first wall 51 can be thermally connected to the second wall 52. Accordingly, the heat of the center 51c of the first wall 51 where the temperature becomes comparatively high in the loop heat pipe 16 can be communicated to the second wall 52. This promotes vaporization of the working fluid 23 in the second portion 61b. By providing the heat connection members 71 in the opposing area 41, vaporization of the working fluid 23 is further promoted.

By forming the heat connection members 71 of the plate members 72 along the flow direction of the working fluid 23 and to extend between the first wall 51 and the second wall 52, it is hard to hinder the flow of the working fluid 23 even if the heat connection members 71 cross the inside of the flow path 21. Accordingly, the operation of the loop heat pipe 16 is easier stabilized.

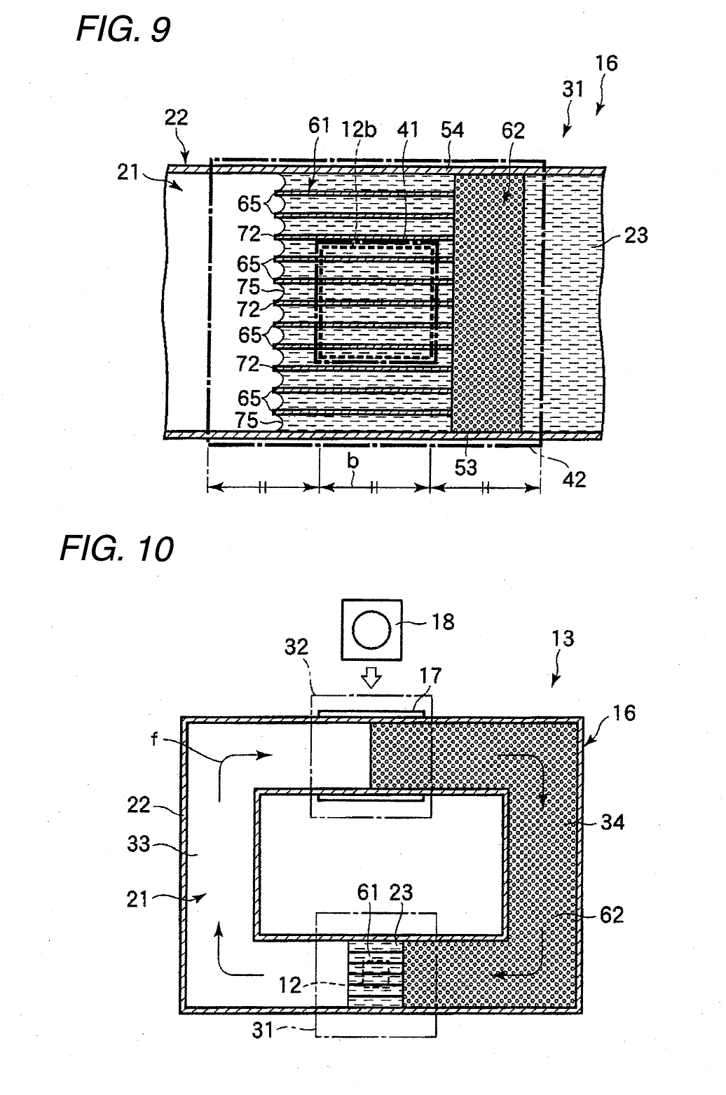

Next, a modified example of the loop heat pipe 16 will be described with reference to FIGS. 8 and 9. As shown in FIG. 8, the first wick 61 may reach the downstream end of the effective evaporation area 42. Further, the first wick 61 may reach the outside of the effective evaporation area 42. In FIGS. 3 and 8, the second wick 62 is provided beyond the upstream end of the effective evaporation area 42. Instead, the second wick 62 may be provided only inside the effective evaporation area 42 as shown in FIG. 9.

Next, a loop heat pipe 16 according to a second embodiment of the invention will be described with reference to FIG. 10. Components identical with or similar to those of the first embodiment previously described with reference to the accompanying drawings are denoted by the same reference numerals in FIG. 10 and will not be described again. The loop heat pipe 16 is installed in a portable computer 1 as an electronic equipment as in the first embodiment, for example.

As shown in FIG. 10, a second wick 62 is provided inside of a liquid return pipe 34 all the way from the condensation part 32 to the evaporation part 31. Other points of the loop heat pipe 16 and the portable computer 1 than those described above are the same as those of the first embodiment.

According to the configuration, a large interface 75 can be formed in a first wick 61, so that the capillary force acting on a working fluid 23 increases and the operation of the loop heat pipe 16 is stabilized as in the first embodiment. Further, if the second wick 62 is provided from the evaporation part 31 to the liquid return pipe 34 and the condensation part 32 as in the second embodiment, entering the working fluid 23 in a vapor phase into the liquid return pipe 34 can be suppressed. Accordingly, the operation of the loop heat pipe 16 is further stabilized.

Thus, if the second wick 62 is provided in many areas, the pressure loss between the condensation part 32 and the evaporation part 31 becomes large and thus generally the working fluid 23 becomes hard to flow. However, according to the configuration of the embodiment, a large capillary force can be provided by the first wick 61, so that the working fluid 23 can be sufficiently circulated if the pressure loss caused by the second wick 62 is somewhat large.

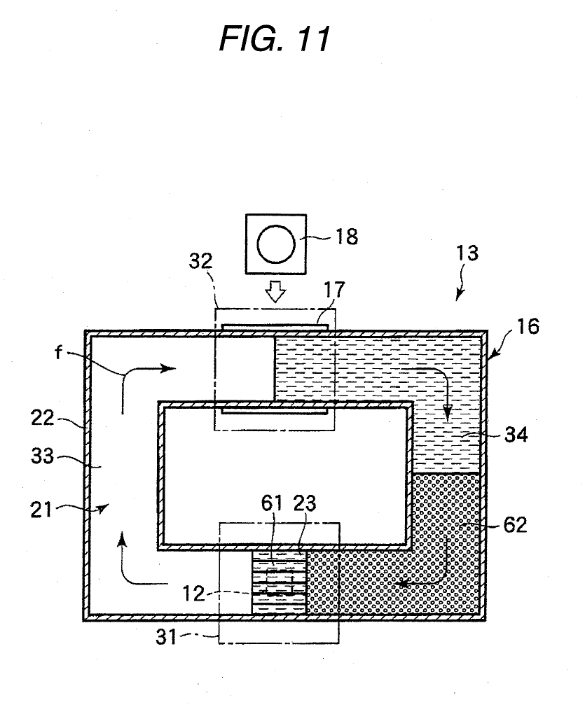

Next, a loop heat pipe 16 according to a third embodiment of the invention will be described with reference to FIG. 11. Components identical with or similar to those of the first embodiment previously described with reference to the accompanying drawings are denoted by the same reference numerals in FIG. 11 and will not be described again. The loop heat pipe 16 is installed in a portable computer 1 as an electronic equipment as in the first embodiment, for example.

As shown in FIG. 11, a second wick 62 is provided entirely from an evaporation part 31 to a midpoint in a liquid return pipe 34. Other points of the loop heat pipe 16 and the portable computer 1 than those described above are the same as those of the first embodiment.

According to the configuration, a large interface 75 can be formed in a first wick 61, so that the capillary force acting on a working fluid 23 increases and the operation of the loop heat pipe 16 is stabilized as in the first embodiment. Further, if the second wick 62 is provided from the evaporation part 31 to the liquid return pipe 34 as in the third embodiment, entering the working fluid 23 in a vapor phase into the liquid return pipe 34 can be suppressed. In FIG. 11, the second wick 62 is provided to a midpoint in the liquid return pipe 34, but may be provided in all of the liquid return pipe 34.

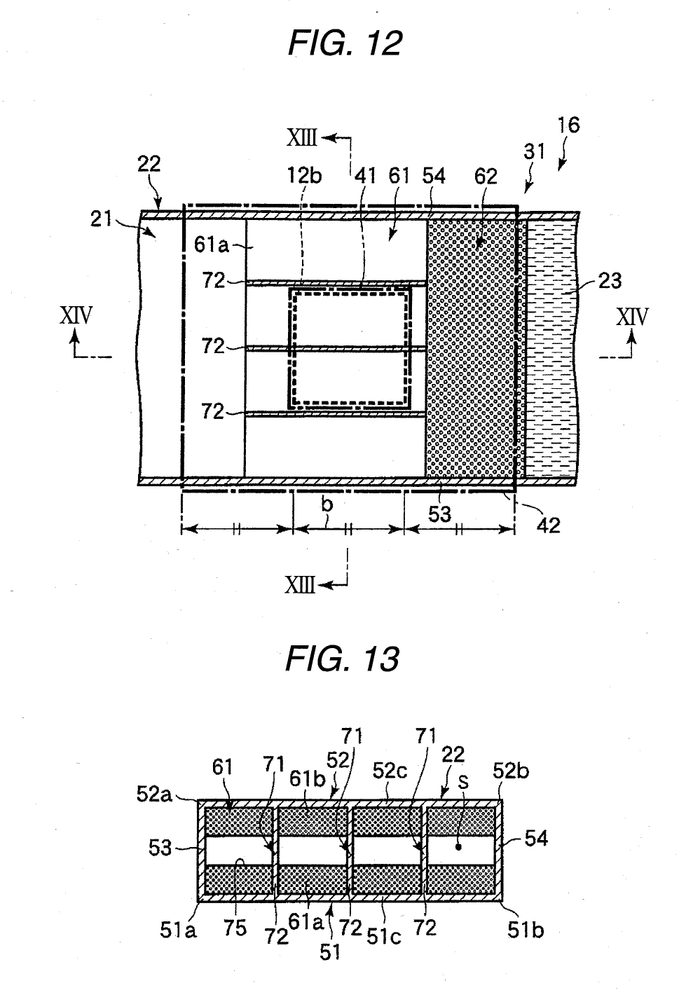

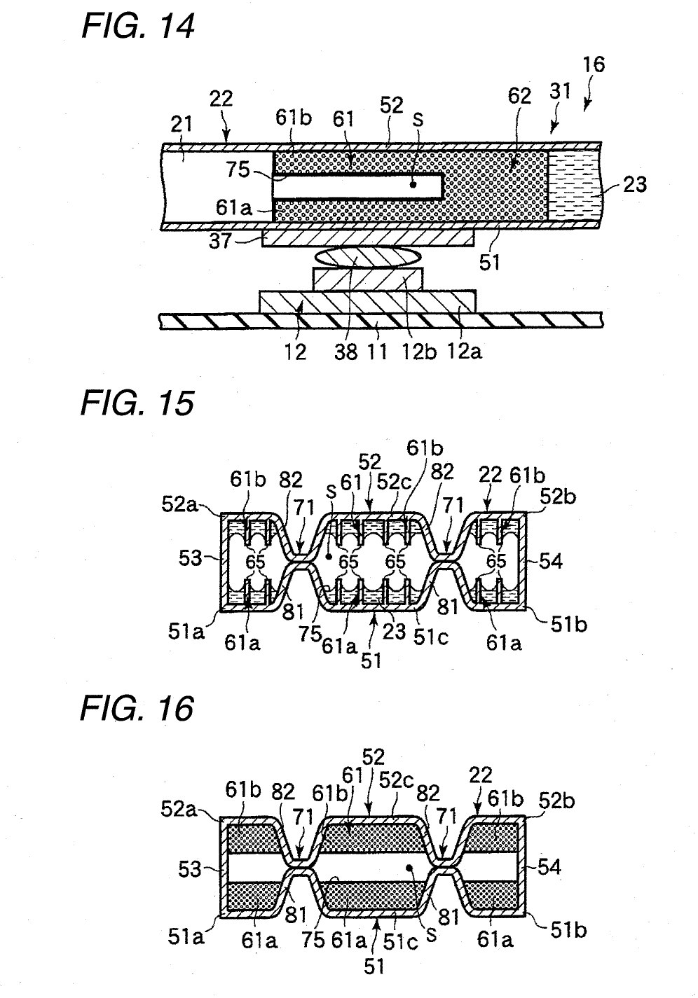

Next, a loop heat pipe 16 according to a fourth embodiment of the invention will be described with reference to FIGS. 12 to 14. Components identical with or similar to those of the first embodiment previously described with reference to the accompanying drawings are denoted by the same reference numerals in FIGS. 12 to 14 and will not be described again. The loop heat pipe 16 is installed in a portable computer 1 as an electronic equipment as in the first embodiment, for example.

Each of first and second wicks 61 and 62 is formed of a porous body. In the fourth embodiment, the first and second wicks 61 and 62 are formed of the same type of porous body and are molded in one piece. The first and second wicks 61 and 62 may be formed of different types of porous body. Other points of the loop heat pipe 16 and the portable computer 1 than those described above are the same as those of the first embodiment.

According to the configuration, a large interface 75 can be formed in the first wick 61, so that the capillary force acting on a working fluid 23 increases and the operation of the loop heat pipe 16 is stabilized as in the first embodiment. If the first and second wicks 61 and 62 are each a porous body, they can be formed at a time.

Next, a loop heat pipe 16 according to a fifth embodiment of the invention will be described with reference to FIG. 15. Components identical with or similar to those of the first embodiment previously described with reference to the accompanying drawings are denoted by the same reference numerals in FIG. 15 and will not be described again. The loop heat pipe 16 is installed in a portable computer 1 as an electronic equipment as in the first embodiment, for example.

As shown in FIG. 15, a first wall 51 is provided in a part with a first convex part 81 projecting toward a second wall 52. The first convex part 81 according to the embodiment is formed as a draw part formed to dent toward the second wall 52. The second wall 52 is provided in a part with a second convex part 82 projecting toward the first wall 51. The second convex part 82 according to the embodiment is formed as a draw part formed to dent toward the first wall 51. The second convex part 82 is provided at a position opposed to the first convex part 81.

The first and second convex parts 81 and 82 are in contact with each other and are thermally connected. In the fifth embodiment, the first and second convex parts 81 and 82 form a heat connection member 71 for thermally connecting the first wall 51 to the second wall 52. The heat connection member 71 is provided between a center 51c of the first wall 51 and a center 52c of the second wall 52. Other points of the loop heat pipe 16 and the portable computer 1 than those described above are the same as those of the first embodiment.

According to the configuration, a large interface 75 can be formed in a first wick 61, so that the capillary force acting on a working fluid 23 increases and the operation of the loop heat pipe 16 is stabilized as in the first embodiment.

By providing the heat connection member 71, heat can also be efficiently communicated to a second portion 61b of the first wick 61 at a distance from the first wall 51. Accordingly, vaporization of the working fluid 23 from the second portion 61b can be promoted. By forming the convex parts 81 and 82 on the heat connection member 71 by projecting a part of at least one of the first and second walls 51 and 52 toward the other, the heat connection member 71 can be formed easily by drawing or any other working method, for example. The convex part need not necessarily be provided on each of the first and second walls 51 and 52; for example, one wall may be provided with a convex part of a size reaching the other wall.

FIG. 16 shows one modified example of the loop heat pipe 16 according to the fifth embodiment of the invention. As shown in FIG. 16, the first wick 61 may be a porous body as in the fourth embodiment in place of the plate member 65.

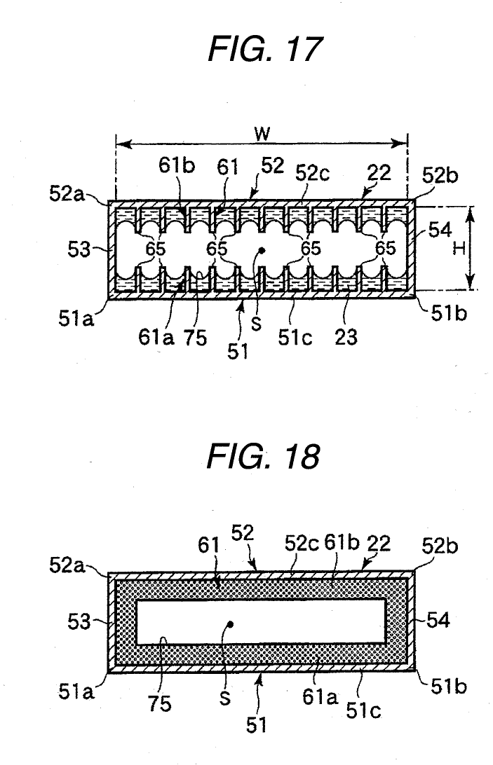

Next, a loop heat pipe 16 according to a sixth embodiment of the invention will be described with reference to FIG. 17. Components identical with or similar to those of the first embodiment previously described with reference to the accompanying drawings are denoted by the same reference numerals in FIG. 17 and will not be described again. The loop heat pipe 16 is installed in a portable computer 1 as an electronic equipment as in the first embodiment, for example.

The loop heat pipe 16 according to the sixth embodiment is provided with no heat connection member 71. A vessel 22 is formed flat and the area of a second wall 52 is larger than the total area of a pair of side walls 53 and 54. Letting width W of a flow path 21 be length A and height H of the flow path 21 be length B, the relation of A>2B holds.

A part of heat that a first wall 51 receives from a heat generating component 12 is communicated to a second portion 61b of a first wick 61 via the pair of side walls 53 and 54 and working fluid 23 in a vapor phase and a liquid phase in the flow path 21. Accordingly, the working fluid 23 is also heated and vaporized in the second portion 61b. Other points of the loop heat pipe 16 and the portable computer 1 than those described above are the same as those of the first embodiment.

According to the configuration, a large interface 75 can be formed in a first wick 61, so that the capillary force acting on the working fluid 23 increases and the operation of the loop heat pipe 16 is stabilized as in the first embodiment. By forming the vessel 22 flat and the area of the second wall 52 is larger than the total area of the pair of side walls 53 and 54, the interface 75 can be formed large by providing the second wall 52 with the second portion 61b of the first wick 61.

FIG. 18 shows one modified example of the loop heat pipe 16 according to the sixth embodiment of the invention. As shown in FIG. 18, the first wick 61 may be a porous body as in the fourth embodiment in place of the plate member 65.

The loop heat pipes 16 according to the first to sixth embodiments and the portable computer 1 in which any of the loop heat pipes 16 have been described, but the invention is not limited to them. The components according to the embodiments may be applied appropriately in combination. For example, also in the fourth to sixth embodiments, the second wick 62 maybe provided from the evaporation part 31 to a midpoint in the liquid return pipe 34 or may be provided in all of the liquid return pipe 34 from the evaporation part 31 or the second wick 62 may be provided from the evaporation part 31 to the condensation part 32 as in the second and third embodiments.

What is claimed is:

1. A loop heat pipe comprising:
a vessel configured to form a flow path in a looped shape; and
a heat transfer fluid sealed in the vessel,
wherein the vessel comprises:
an evaporation unit thermally connected to a heat generating component for vaporizing the heat transfer fluid, the evaporation unit comprising an area opposed to the heat generating component;
a condensation unit configured to liquefy the vaporized heat transfer fluid;
a steam pipe connected between the evaporation unit and the condensation unit, and configured to allow the heat transfer fluid vaporized at the evaporation unit to flow toward the condensation unit;
a liquid return pipe connected between the condensation unit and the evaporation unit, configured to allow the heat transfer fluid condensed at the condensation unit to flow toward the evaporation unit;
a first wick provided in the flow path at the opposing area of the evaporation unit; and
a second wick provided in the flow path to be adjacent to the first wick at a side of the liquid return pipe,
wherein the evaporation unit comprises a first wall facing the heat generating component and a second wall opposed to the first wall,
wherein the first wick comprises a first portion provided on the first wall and a second portion provided on the second wall separated from the first portion,
wherein the second wick is provided to cover the entire cross-section of the flow path between the first wall and the second wall, and
wherein the evaporation unit comprises a heat connection member extending from the first wall through the flow path to the second wall in order to thermally connect the first wall and the second wall.

2. The loop heat pipe of claim 1, wherein the first and second portions of the first wick are formed of a plurality of plate members disposed along a flow direction of the heat transfer fluid.

3. The loop heat pipe of claim 1, wherein the second wick is formed of a porous body.

4. The loop heat pipe of claim 1, wherein the heat connection member is formed of a plate member disposed along a flow direction of the heat transfer fluid, extending between the first wall and the second wall.

5. The loop heat pipe of claim 1, wherein both of the first wick and the second wick are formed of a porous body.

6. A loop heat pipe comprising:
a vessel configured to form a flow path in a looped shape; and
a heat transfer fluid sealed in the vessel,
wherein the vessel comprises:
an evaporation unit thermally connected to a heat generating component for vaporizing the heat transfer fluid, the evaporation unit comprising an area opposed to the heat generating component;
a condensation unit configured to liquefy the vaporized heat transfer fluid;
a steam pipe connected between the evaporation unit and the condensation unit to allow the heat transfer fluid vaporized at the evaporation unit to flow toward the condensation part;
a liquid return pipe connected between the condensation unit and the evaporation unit to allow the heat transfer fluid condensed at the condensation unit to flow toward the evaporation unit;
a first wick provided in the flow path at the opposing area of the evaporation unit; and
a second wick provided in the flow path to be adjacent to the first wick at a side of the liquid return pipe,
wherein the evaporation unit comprises a first wall facing the heat generating component and a second wall opposed to the first wall,
wherein the first wick comprises a first portion provided on the first wall and a second portion provided on the second wall separated from the first portion, and
wherein the second wick is provided to cover the entire cross-section of the flow path between the first wall and the second wall.

7. The loop heat pipe of claim 6, wherein each of the first and second walls has a pair of side edges extending along a flow direction of the heat transfer fluid,
wherein the evaporation unit comprises a pair of side walls connected between the side edges of the first wall and the corresponding side edges of the second wall, and
wherein the evaporation unit is formed in a flat tube shape, in which an area of the second wall is configured to be larger than a total area of the side walls.

8. The loop heat pipe of claim 6, wherein the evaporation unit comprises a heat connection member thermally connected between the first wall and the second wall.

9. The loop heat pipe of claim 8, wherein the heat connection member is formed of a convex part formed by projecting a portion of either the first or second wall toward the second or first wall, respectively, or both.

10. An electronic equipment comprising:
a cabinet;
a heat generating component installed in the cabinet; and
a loop heat pipe comprising:
a vessel that forms a flow path in a looped shape; and
a heat transfer fluid sealed in the vessel, wherein the vessel comprises:
an evaporation unit thermally connected to a heat generating component for vaporizing the heat transfer fluid, the evaporation unit comprising an area to be opposed to the heat generating component;
a condensation unit configured to liquefy the vaporized heat transfer fluid;
a steam pipe connected between the evaporation unit and the condensation unit to allow the heat transfer fluid vaporized at the evaporation unit to flow toward the condensation unit;
a liquid return pipe connected between the condensation unit and the evaporation unit to allow the heat transfer fluid condensed at the condensation unit to flow toward the evaporation part;
a first wick provided in the flow path at the opposing area of the evaporation unit; and
a second wick provided in the flow path to be adjacent to the first wick at a side of the liquid return pipe,
wherein the evaporation unit comprises a first wall facing the heat generating component and a second wall opposed to the first wall,
wherein the first wick comprises a first portion provided on the first wall and a second portion provided on the second wall separated from the first portion, and
wherein the second wick is provided to cover the entire cross-section of the flow path between the first wall and the second wall.
